(19) United States
(12) Patent Application Publication
(10) Pub. No.: US 2026/0150506 A1
(43) Pub. Date: May 28, 2026

(54) ELECTROLUMINESCENT SUBSTRATE AND ELECTROLUMINESCENT DEVICE INCLUDING THE SAME

(71) Applicant: Najing Technology Corporation Limited, Hangzhou, Zhejiang (CN)

(72) Inventors: Junjun PENG, Hangzhou, Zhejiang (CN); Changgua ZHEN, Hangzhou, Zhejiang (CN)

(73) Assignee: Najing Technology Corporation Limited, Hangzhou, Zhejiang (CN)

(21) Appl. No.: 19/109,895

(22) PCT Filed: Aug. 30, 2023
(86) PCT No.: PCT/CN2023/115672

§ 371 Date: Jan. 26, 2026

(30) Foreign Application Priority Data
Sep. 9, 2022 (CN) 202211101386.6

(51) Int. Cl. H10K 59/122; H10K 59/124; H10K 59/35; H10K 102/00

(52) U.S. Cl. CPC H10K 59/122; H10K 59/124; H10K 59/352; H10K 2102/351

(57) ABSTRACT

The present disclosure relates to an electroluminescent substrate and an electroluminescent device including the electroluminescent substrate. The electroluminescent substrate includes a substrate layer with pixel driving circuitry and an array of pixel areas arranged on the substrate. The pixel areas are defined by a pixel isolation structure, and at least a portion of the pixel areas includes a first electrode layer, a first insulating layer disposed on the first electrode layer, and multiple blank layers. Each blank layer is formed by and surrounded by at least a portion of the first insulating layer and separated from each other. The pixel isolation structure has a thickness greater than the thickness of the first insulating layer. At least a portion of the pixel areas has an interval in the interior of the corresponding first electrode layer. By combining the pixel isolation structure and the first insulating layer, the advantages of both can be utilized, which avoids color mixing and ensures the uniformity of the light-emitting layer thickness. Additionally, the design of the intervals further improves the emission uniformity or density of the electroluminescent device.

### TECHNICAL FIELD

The present disclosure relates to the field of optoelectronic device, and more specifically, to an electroluminescent substrate and an electroluminescent device including the same.

### BACKGROUND

Light-emitting devices such as light-emitting diodes are widely used in the fields of lighting and display. In a display device, a pixel definition layer (PDL) is usually provided for defining pixels. Typically, the pixel defining layer is presented in the form of a pixel isolation (or bank) structure for defining the pixels (or sub-pixels), thereby separating the pixels (or sub-pixels). The inventors of the present disclosure have found that when printed ink dries within a sub-pixel pit, the pixel isolation structure (or bank) has a significant adsorption effect on the ink, resulting in a distribution of ink material deposited within the sub-pixel pit that is thicker near the edges of the bank and thinner in the middle portion of the sub-pixel (e.g., the center of the sub-pixel's active area). In order to compensate for the thin film thickness in the middle portion of the sub-pixel, there is a tendency to increase the ink volume in the sub-pixel pit as much as possible while ensuring that the ink does not overflow, i.e., to increase the total amount of material in the sub-pixel pit. Although this effect can also be achieved by increasing the ink concentration, the risk of clogging of the printhead or cutterhead of a printing device is substantially increased; in contrast, increasing the volume within the sub-pixel pit by increasing the height of the bank is more robust and easier to realize in terms of process. In the existing pixel designs for a solution-processed electroluminescent device, the mainstream bank height is around 2 μm or higher. Although the larger volume of the sub-pixel pit compensates for the less material thickness in the center of the sub-pixel pit, it has been found that the higher bank results in a more significant ink adsorption, leading to a more uneven film thickness distribution within the sub-pixel pit.

### SUMMARY

According to one aspect, an electroluminescent substrate is provided, the electroluminescent substrate includes a substrate layer comprising pixel driving circuitry, and an array of pixel areas disposed on the substrate layer; the pixel areas being defined by a pixel isolation structure, at least a portion of the pixel areas comprising a first electrode layer, a first insulating layer disposed on the first electrode layer, and a plurality of blank layers; each blank layer being formed by and surrounded by at least a portion of the first insulating layer and separated from each other, the pixel isolation structure having a thickness greater than the thickness of the first insulating layer;
the pixel isolation structure comprising a plurality of isolation pillars arranged in at least one direction; an orthographic projection of the pixel isolation structure on the electroluminescent substrate does not overlap with an orthographic projection of the blank layer on the electroluminescent substrate;
the interior of the first electrode layer corresponding to at least a portion of the pixel areas has an interval such that the first electrode layer is disconnected and forms a plurality of sub-first electrode layers arranged in a mutually spaced manner, the interior of the first insulating layer also being separated by the interval; the number of the intervals in the at least a portion of the pixel areas is greater than or equal to 1; a second insulating layer is provided inside the intervals;
the electroluminescent substrate further comprising one or both of feature A and feature B,
the feature A being that the pixel isolation structure is disposed on a portion of the first insulating layer, the orthographic projection of the pixel isolation structure on the electroluminescent substrate falls within an area of the orthographic projection of the corresponding first insulating layer on the electroluminescent substrate;
the feature B characterized in that the pixel isolation structure is disposed on a portion of the first electrode layer and at least a portion of the first insulating layer and the pixel isolation structure are disposed in transverse contact.

Furthermore, the first insulating layer has a thickness of less than 700 nm.

Furthermore, the pixel isolation structure has a thickness of 0.7 to 2 μm.

Furthermore, the depth of the interval does not reach the substrate layer, and the thickness of the second insulating layer is less than or equal to the thickness of the first electrode layer.

Furthermore, the second insulating layer is in contact with the substrate layer or the second insulating layer is disposed within the substrate layer, preferably, the second insulating layer has a thickness of less than 700 nm.

Furthermore, a side boundary line L1 of the orthographic projection of the isolation pillar arranged along a first direction on the electroluminescent substrate is parallel to a side boundary line L3 of the orthographic projection of the blank layer on the electroluminescent substrate, with the shortest distance d1 between L1 and L3 being 1 to 15 μm.

Furthermore, the width d2 of the interval ranges from 1 to 15 μm.

Furthermore, within a single pixel area: the number of the intervals is 1, the interval is disposed in the center of the pixel area, and the blank layer corresponding to the pixel area has two columns; or, the number of the intervals is 2, each of the intervals is adjacent to one side of the isolation pillar arranged in a first direction, and the pixel area corresponding to the blank layer has one column; or, the number of the intervals is 3, two of the intervals are each adjacent to one side of the isolation pillar arranged in a first direction, one interval is disposed in the center of the pixel area, and the blank layer corresponding to the pixel area has two columns.

Furthermore, when the number of the intervals is 2 or 3, a side boundary line L1 of the orthographic projection of the isolation pillars arranged in the first direction on the electroluminescent substrate overlaps with a side boundary line L2 of the orthographic projection of the corresponding the first insulating layer on the electroluminescent substrate, or the orthographic projection of the blank layer on the electroluminescent substrate has a side boundary line L3, L1 is parallel to L2 and L3, and L1 is spaced away from the L3.

Furthermore, the first insulating layer is uniform in thickness and material throughout the layer.

Furthermore, the material of the first insulating layer is selected from SiNₓ or SiO₂.

Furthermore, the plurality of blank layers are arranged in an elongate strip shape within a single pixel area, the blank layer comprising at least one column and each blank layer has the same area, and the length direction of the blank layers being the same as the extension direction of the isolation pillars arranged in a first direction.

Furthermore, the electroluminescent substrate includes at least three pixel areas, the blank layers disposed in the first and the third pixel areas are both in two columns and each blank layer has an area of S1, the blank layer disposed in the second pixel area is in one column and each blank layer has an area of S2, the first, second and third pixel areas are arranged side by side.

Furthermore, the pixel isolation structure further includes isolation pillars arranged in a second direction, the width direction of the blank layer being in the same direction as the extension direction of the isolation pillars arranged in the second direction; the electroluminescent substrate comprising at least three pixel areas, the blank layers disposed in the first and third pixel areas being in two columns and area of each of the blank layers is S1, the blank layers disposed within the second pixel area are in two columns and area of each of the blank layers is S2, the first and third pixel areas are both defined by the isolation pillars arranged in the first direction and the isolation pillars arranged in the second direction, and the second pixel area is defined only by the isolation pillars arranged in the first direction.

Furthermore, the first pixel area is the area for setting a red light-emitting element, the second pixel area is the area for setting a blue light-emitting element, the third pixel area is the area for setting a green light-emitting element, and each of the blank layers disposed in the same pixel area is used for setting light-emitting elements of the same light-emitting color.

Furthermore, S1 is smaller than S2, preferably, S2=2S1.

According to another aspect, an electroluminescent device is provided, it includes an electroluminescent substrate as described in any embodiment.

With the above technical solutions, by combining both the pixel isolation structure and the first insulating layer, the advantages of the pixel isolation structure and the first insulating layer can be utilized at the same time, i.e., to avoid mixing of colors and to ensure the uniformity of the film thickness in the emission area. In addition, the specifically designed interval can remove an area that may cause uneven light emission of the film, thereby the area in the electroluminescent device does not emit light, thereby improving the uniformity of emission of the electroluminescent device; or the specifically designed interval can further segment the pixel, thereby increasing the pixel density.

Other features of the present disclosure and advantages thereof will become clearer by the following detailed description of exemplary embodiments of the present disclosure with reference to the accompanying drawings.

### BRIEF DESCRIPTION OF THE DRAWINGS

The foregoing and other features and advantages of the present disclosure will become clear from the following description of embodiments of the present disclosure illustrated in conjunction with the accompanying drawings. The accompanying drawings, which are incorporated herein and form part of the specification, are further used to explain the principles of the present disclosure and to enable those skilled in the art to make and use the present disclosure. Among them:

FIGS. 1-2 illustrate schematic cross-sectional views of an electroluminescent substrate in accordance with some embodiments of the present disclosure.

FIG. 3 illustrates a top schematic view of an electroluminescent substrate according to some embodiments of the present disclosure.

FIGS. 4-7 illustrate a schematic cross-sectional view of an electroluminescent substrate according to some embodiments of the present disclosure.

FIGS. 8-9 illustrate a top schematic view of an electroluminescent substrate according to some embodiments of the present disclosure.

FIGS. 10-13 illustrate a schematic cross-sectional view of an electroluminescent substrate according to some embodiments of the present disclosure.

FIG. 14 illustrates a top schematic view of an electroluminescent substrate according to some embodiments of the present disclosure.

FIG. 15 illustrates a schematic view of a pixel arrangement design of an electroluminescent substrate according to some embodiments of the present disclosure.

FIG. 16 illustrates a schematic view of a pixel arrangement design of an electroluminescent substrate according to some embodiments of the present disclosure.

FIG. 17 illustrates a microscope photograph of an example of an RGB quantum dot light-emitting layer (without drying) on an electroluminescent substrate after it has been prepared and excited by UV light.

FIG. 18 illustrates a microscope photograph of a RGB electroluminescent device in the light-emitting state of an example.

FIG. 19 illustrates a microscope photograph of a RGB electroluminescent device in the light-emitting state of yet another example.

1, substrate layer; 2, first electrode layer; 3, first insulating layer; 4, pixel isolation structure; 5, blank layer; 6, second insulating layer; Z, pixel area; PX, pixel unit.

Note that in the embodiments illustrated below, sometimes the same accompanying markings are used in common between different accompanying drawings to denote the same portion or portions having the same function, and their repeated description is omitted. In some instances, similar labels and letters are used to denote similar items, so that once an item is defined in one of the accompanying drawings, no further discussion thereof is required in the subsequent accompanying drawings.

For ease of understanding, the positions, dimensions and ranges, etc., of the various structures shown in the accompanying drawings, etc., sometimes do not indicate actual positions, dimensions and ranges, etc. Accordingly, the present disclosure is not limited to the positions, dimensions and ranges, etc. disclosed in the accompanying drawings and the like.

### DETAILED DESCRIPTION

Various exemplary embodiments of the present disclosure will be described in detail below with reference to the accompanying drawings. It should be noted that the relative arrangements, numerical expressions, and values of the components and steps set forth in these embodiments do not limit the scope of the present disclosure unless otherwise specifically stated.

The following description of at least one exemplary embodiment is in fact merely illustrative and in no way serves as any limitation on the present disclosure and its application or use. That is, the structures and methods herein are shown in an exemplary manner to illustrate different embodiments of the structures and methods of the present disclosure. However, those skilled in the art will understand that they are merely illustrative of exemplary ways in which the present disclosure can be implemented and are not exhaustive. In addition, the accompanying drawings need not be drawn to scale, and some features may be enlarged to show details of specific components.

In addition, techniques, methods, and apparatus known to one of ordinary skill in the relevant field may not be discussed in detail, but where appropriate, said techniques, methods, and apparatus should be considered part of the granted specification.

In all of the examples illustrated and discussed herein, any specific values should be interpreted as merely exemplary and not as limitations. Thus, other examples of exemplary embodiments may have different values.

At present, electroluminescent device is usually produced by vacuum evaporation process or solution process, especially a specific function layer of QLED can only be produced by solution process, which mainly adopts inkjet printing process. In the printing process, technicians generally believe that it is necessary to define the pixels on the electroluminescent substrate with a pixel isolation structure, because without such pixel isolation structure, it would be easy for different pixels to come into contact with each other and interfere with each other's colors. In order to achieve a good isolation effect, the height of the pixel isolation structure is often set to be as high as several micrometers, which greatly exceeds the height of the stack of functional layers of the electroluminescent device. The stack of functional layers may include, but is not limited to, at least two of the following: a hole injection layer, a hole transport layer, a hole blocking layer, a light-emitting layer, an electron injection layer, an electron transport layer, an electron blocking layer, and a buffer layer. In the context of the present disclosure, the stack of functional layers may include any layer in the light-emitting element, other than the electrode layer and the first insulating layer, that has an effect on the light-emitting or luminescent performance of the device. In other words, the stack of functional layers may include any and all layers that may be disposed in the emission area of the light-emitting device between the first electrode and the second electrode.

When the light-emitting layer or the functional layer, for example, is prepared by an inkjet printing process, the ink droplets are affected by capillary effects at the edges around the pixel isolation structure, and accumulate at the edges of the bank after drying, resulting in a non-uniform film, which results in a poor light-emitting performance of the prepared electroluminescent device. When a plurality of functional or light-emitting layers are formed, this edge accumulation phenomenon aggravates layer by layer.

In view of all the above problems caused by the pixel isolation structure, the inventors of the present disclosure have improved on the electroluminescent substrate of the conventional pixel isolation structure, and provided the electroluminescent substrate having a novel structure for the electroluminescent device. Embodiments of the present disclosure are specifically described below in conjunction with the accompanying drawings. In different embodiments, the electroluminescent substrate according to various embodiments of the present disclosure may be a bottom-emitting electroluminescent substrate that emits light through a bottom electrode and a substrate, a top-emitting electroluminescent substrate that emits light through a top electrode, or a bottom-emitting electroluminescent substrate that emits light from both the bottom and the top surfaces.

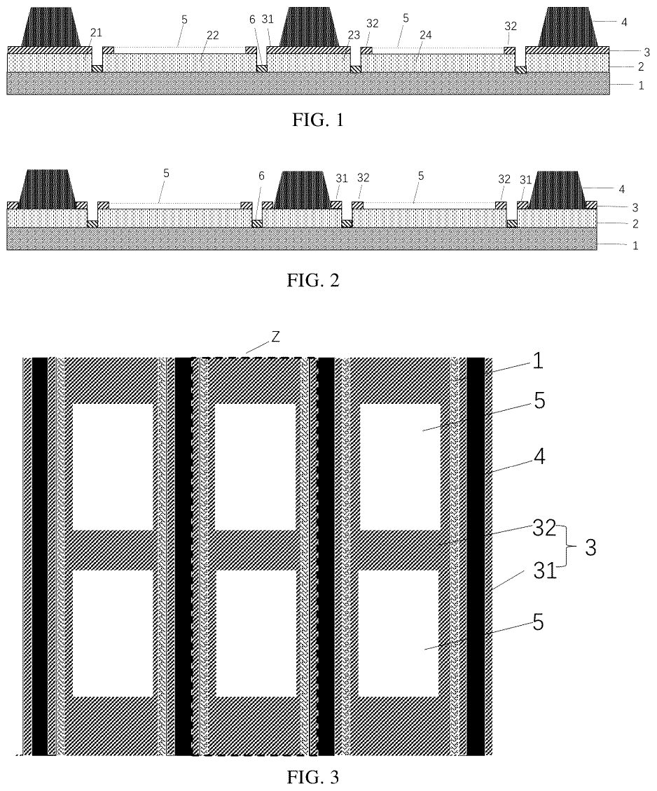

FIGS. 1-2 illustrate a schematic diagram of a cross-section of an electroluminescent substrate according to some embodiments of the present disclosure. The electroluminescent substrate includes a substrate layer 1 including pixel driving circuitry and an array of pixel areas disposed on the substrate layer 1. The pixel areas are defined by a pixel isolation structure 4, at least a portion of the pixel areas includes a first electrode layer 2, a first insulating layer 3 disposed on the first electrode layer 2, and a plurality of blank layers 5 (some of the lines are dashed). Each blank layer 5 is formed by and surrounded by at least a portion of the first insulating layer 3 and separated from each other. The thickness of the pixel isolation structure 4 being greater than the thickness of the first insulating layer 3; the pixel isolation structure 4 including a plurality of isolation pillars arranged in at least one direction; the orthographic projection of the pixel isolation structure 4 on the electroluminescent substrate does not overlap with the orthographic projection of the blank layer 5 on the electroluminescent substrate (i.e., there is a certain distance between the two orthographic projections). As shown in FIG. 1, the electroluminescent substrate further including feature A: the pixel isolation structure 4 is disposed on a portion of the first insulating layer 3, and the orthographic projection of the pixel isolation structure 4 on the electroluminescent substrate falls within an area of the orthographic projection of the corresponding first insulating layer 3 on the electroluminescent substrate (as described later, because the first insulating layer 3 is segmented by interval, herein, “the corresponding first insulating layer 3” refers to a portion of the first insulating layer 3 that supports the pixel isolation structure 4); or as shown in FIG. 2, the electroluminescent substrate further includes a feature B: the pixel isolation structure 4 is disposed on a portion of the first electrode layer 2, and at least a portion of the first insulating layer 3 and the pixel isolation structure 4 are disposed in transverse contact (as described hereinafter, since the first insulating layer 3 is separated by interval, there is an interval between the “portion of the first insulating layer 3” and the other portion of the first insulating layer 3); or the electroluminescent substrate includes both feature A and feature B described above. FIG. 3 shows a top view of the electroluminescent substrate shown in FIGS. 1-2, with the area defined by the adjacent pixel isolation structure 4 (the area inside the dashed box is marked as “Z”) defined as a pixel area, and within the pixel area there is at least one blank layer 5. As an example only, FIG. 3 illustrates three pixel areas, the interior of the first electrode layer corresponding to the at least a portion of the pixel areas has an interval such that the first electrode layer is disconnected and forms a plurality of sub-first electrode layers arranged in a mutually spaced manner (see marks 21, 22, 23, 24 of FIG. 1); the number of interval within the at least a portion of the pixel areas is greater than or equal to 1, and the interior of the first insulating layer 3 is also separated by intervals (see marks 31, 32 of FIGS. 1-2), a second insulating layer 6 is provided inside the intervals.

It should be noted that the structures of the “first electrode layer” corresponding to the pixel isolation structure (e.g., 21 and 23 in FIG. 1), the first insulating layer corresponding to the pixel isolation structure (e.g., 31 in FIG. 1), and the “substrate layer including pixel driving circuitry” in the accompanying drawings are only schematic and do not represent actual structures, and the actual structures may be referred to the prior art or appropriately varied, and the present disclosure is not limited thereto. The “first electrode layer” corresponding to the pixel isolation structure is not limited to a continuous state, it can be a non-continuous state.

“Blank layer” means that before the substrate is used for the preparation of the electroluminescent device/apparatus, no material, such as a material of functional layer or a material of light-emitting layer, has been provided therein, and the blank layer can be regarded as a groove due to the partial encirclement of the first insulating layer 3, which is used for the subsequent disposition of the light-emitting material and/or the functional layer material to obtain the light-emitting layer and the functional layer. The height of the light-emitting layer and the functional layer may be greater than the height of the blank layer 5 (or the depth of the groove).

“Disposed in an array” means any regular arrangement with repeating units, such as n rows×n columns, but is not limited thereto.

“Electroluminescent substrate” does not refer to a substrate that emits light, but to a substrate used for an electroluminescent device.

As examples, the first electrode 2 may include one or more layers of conductive material, for example, indium tin oxide (ITO) or indium zinc oxide, or a stack of indium tin oxide (ITO)/silver (Ag)/ITO, or a stack of indium zinc oxide (IZO)/Ag/IZO. It should be understood that the present disclosure is not limited thereto.

In the above-described electroluminescent substrate, the shorter first insulating layer 3, no only defines the blank layer (corresponding to the emission area of the electroluminescent device), but also at the same time reduces the unevenness of the film caused by the accumulation at the edges due to capillary effect. The inventors believe that if the scheme of completely discarding the pixel isolation structure or only including the shorter pixel isolation structure is adopted, avoiding color mixing would require very high precision in printing and the ink spread control, and to reduce the difficulty of the printing process and improve the printing yield, it is generally necessary to leave a larger non-emission area to prevent color mixing, although this will sacrifice the aperture ratio. Therefore, by combining both the pixel isolation structure 4 and the first insulating layer 3, the advantages of both can be utilized simultaneously, i.e., to avoid mixing of colors and to ensure the uniformity of the thickness of the film in the emission area. In addition, the design of the intervals removes areas that may cause uneven light emission, thus preventing these areas from emitting light and improving the uniformity of the light emitted by the electroluminescent device. The specific design of the intervals also further divides the pixels, thereby increasing the pixel density or Pixels Per Inch (PPI).

The plurality of blank layers 5 described above are spaced apart due to the presence of the first insulating layer 3, and in some embodiments, each of the two adjacent blank layers 5 in the same column are equally spaced apart in the length direction (the extension direction of the column). In some embodiments, the individual blank layers 5 are separated from each other by equal intervals, such as both in the length direction and in the width direction. In some embodiments, the interval of the blank layers 5 from the isolation pillars is equal to the interval of two neighboring blank layers 5 in the length direction (using the top view as a comparison view). In some embodiments, the pixel isolation structure 4 includes only a plurality of mutually parallel isolation pillars arranged in one direction, the isolation pillars being arranged in an elongate strip shape, the blank layers 5 being arranged in an elongate strip shape, and preferably the individual blank layers themselves being in an elongate strip shape (the elongate strip shape refers to an elongate strip arrangement when viewed from the perspective of the top view). Thanks to the presence of the first insulating layer 3, there is no need for the isolation pillars of the pixel isolation structure 4 to be designed as in the prior art to be surrounded on all sides, similar to a mesh fence structure. The elongate arrangement of the blank layers 5 is very suitable for the printing process. For example, the ink of the same light emitting material can be printed within the same column of blank layers 5. The individual blank layers 5 in the same column can be used for the same ink due to the lower thickness of the first insulating layer 3. The ink flow sufficiently in all directions beyond the thickness of the first insulating layer 3 without concern of color mixing, thus simplifying the preparation process of the electroluminescent device. In some embodiments, the pixel isolation structure 4 includes a plurality of isolation pillars arranged in two non-parallel directions, enabling more diverse combinations of pixel arrangements. The above pixel driving circuitry may be an AM driving circuitry or a PM driving circuitry.

In some embodiments, the first insulating layer 3, as shown in 31 and 32 in FIGS. 1-2, is disposed on both sides of the interval, and completely covers the etched edges of the corresponding sub-first electrode layer, so as to minimize leakage or short-circuit issues of the sub-first electrode layer due to the sharpness generated by the preparation process.

In some embodiments, the pixel isolation structure 4 has a substantially flat top surface. The pixel isolation structure 4 may be formed from an inorganic or organic material, preferably an organic material thereby forming a greater thickness. Examples for said inorganic material include, but not limited to, silicon nitride, silicon dioxide. Said organic material may be, for example, a photoresist including a fluorine-containing or non-fluorine-containing polyimide resin.

In some embodiments, the cross-sectional shape of the interval structure may be trapezoidal, inverted trapezoidal, rectangular, or an approximate shape corresponding to these. The term “approximate shape” also refers to shapes that include one or more arcs.

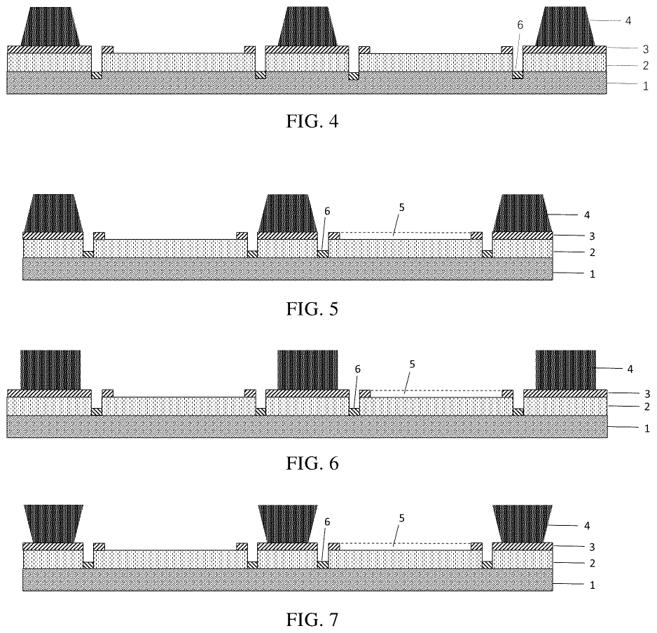

In some embodiments, as shown in FIGS. 1-2, the depth of the interval does not reach the substrate layer 1. In other embodiments, as shown in FIG. 4, the depth of the interval reaches the substrate layer 1.

In some embodiments, the thickness of the first insulating layer 3 is less than 700 nm. The inventors of the present disclosure have found that by setting the thickness of the first insulating layer 3 to 700 nm or less, the film unevenness of the light-emitting layer and/or the functional layer near the first insulating layer 3 caused by capillary effect at the edges can be reduced, and thus the uniformity of the film can be improved.

Preferably, the thickness of the first insulating layer 3 is less than or equal to 500 nm, more preferably less than or equal to 400 nm, more preferably in the range of greater than 50 nm to 200 nm. When the thickness of the first insulating layer 3 is 200 nm or even less, the edges of the functional layer disposed within the blank layer 5 can be free of accumulation during the preparation of light-emitting device. Furthermore, when the thickness of the first insulating layer 3 is 200 nm or less, the problem of poor contact stability of the upper (second) electrode, which is thinner, can be completely avoided. Since the thickness of the printed ink is typically several micrometers after spreading, the first insulating layer 3 has less impact on the flow of the ink. This reduces or eliminates the accumulation at the edges of the functional layer, and thus increases the effective emission area of the pixel.

In some embodiments, the thickness of the pixel isolation structure 4 is from 0.7 to 2 μm. Preferably, the thickness of the pixel isolation structure 4 is 0.8 to 1.2 μm. The pixel isolation structure 4 may be as thin as possible while fulfilling the function of limiting the ink overflow. The thicknesses of the isolation pillars in different arrangement directions are not necessarily equal.

In some embodiments, the thickness of the second insulating layer 6 is less than or equal to the thickness of the first electrode layer 2 when the depth of the interval does not reach the substrate layer 1. In some embodiments, the second insulating layer 6 and the first insulating layer 3 are produced simultaneously.

In some embodiments, the second insulating layer 6 is provided in contact with the substrate layer 1 or the second insulating layer 6 is disposed within the substrate layer 1. Preferably, the thickness of the second insulating layer 6 is equal to the thickness of the first insulating layer 3.

In some embodiments, the orthographic projection of the pixel isolation structure 4 (or the isolation pillars arranged in the first direction) on the electroluminescent substrate overlaps with the orthographic projection of the corresponding first insulating layer 3 on the electroluminescent substrate. As shown in FIG. 5, that is, the bottoms of both overlap.

In some embodiments, the cross-section of the isolation pillar of the pixel isolation structure 4 may be trapezoidal, inverted trapezoidal, or rectangular. As shown in FIGS. 6-7, the cross-sections of the isolation pillars of the pixel isolation structure 4 are rectangular, inverted trapezoidal.

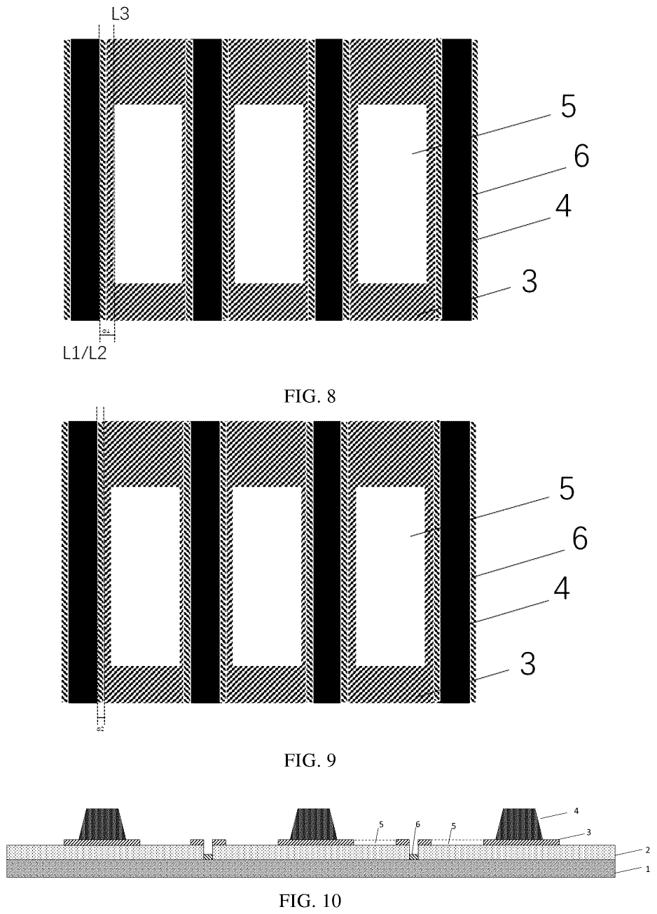

In some embodiments, a side boundary line L1 of the orthographic projection of the isolation pillars arranged along a first direction on the electroluminescent substrate is parallel to a side boundary line L3 of the orthographic projection of the blank layer 5 on the electroluminescent substrate and the shortest distance d1 between L1 and L3 is 1 to 15 μm. The top view of the electroluminescent substrate of FIG. 5 refers to FIG. 8, wherein the position of d1 (the distance between the two dashed lines) is illustrated. In some embodiments, preferably d1 is 4 to 6 μm.

In some embodiments, the width of the interval d2 is 1 to 15 μm. The top view of the electroluminescent substrate of FIG. 5, as shown in FIG. 9, shows the position of d2 (the distance between two dashed lines). From the above definitions of d1 and d2, we know that d1 is larger than d2. In some embodiments, it is preferred that d2 is 4 to 6 μm. The main determining factors for the ranges of d1 and d2 are the width of the uneven area and the fabrication accuracy of the insulating layer.

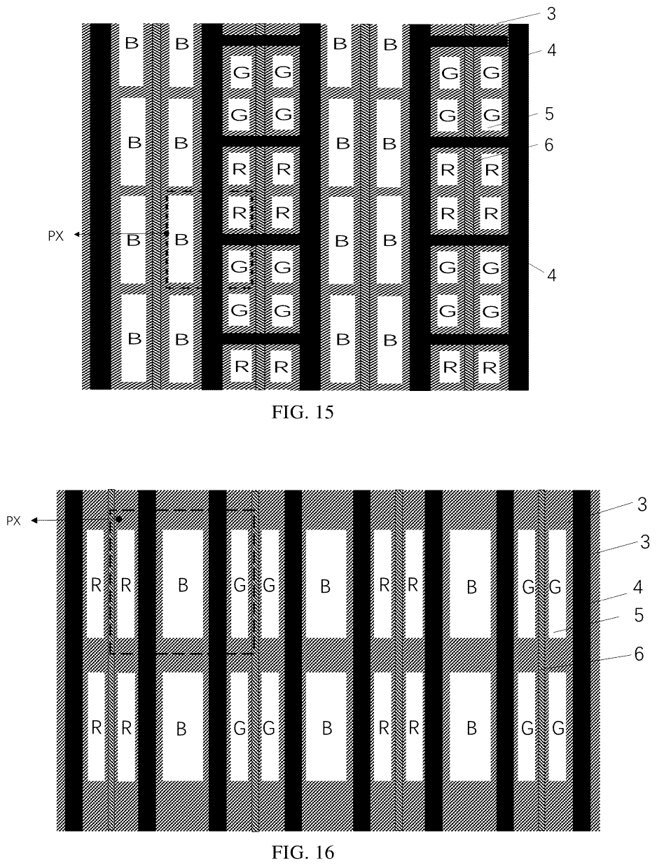

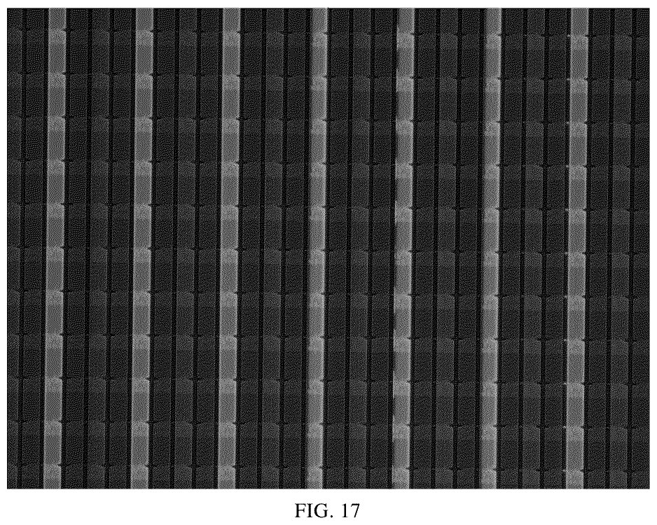

In some embodiments, within a single pixel area: when the number of interval is 1, the interval is disposed in the center of the pixel area, and the corresponding blank layer 5 within the pixel area consists of two columns (e.g., FIGS. 10-12); when the number of interval is 2 (e.g., FIGS. 1-2, FIGS. 4-7), each interval is adjacent to one side of the isolation pillar arranged in the first direction, and the corresponding blank layer 5 within the pixel area has one column; or the number of intervals is 3 (e.g., FIG. 13), two intervals are each adjacent to one side of the isolation pillar arranged in the first direction, one interval is disposed in the center of the pixel area, and the corresponding blank layer 5 within the pixel area consists of two columns.

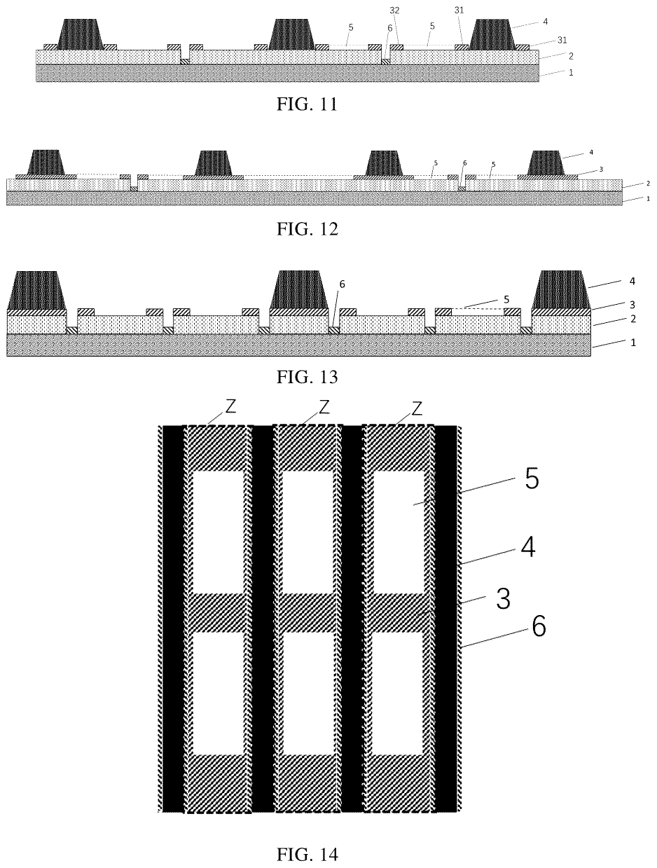

In some embodiments, disposing the interval in the center of the pixel area enables pixel segmentation and improves the PPI of the display. In order to improve the luminous uniformity, see FIGS. 10-12 for the pixel isolation structure and the design of the first insulating layer. As shown in FIGS. 10 and 12, the orthographic projection of the pixel isolation structure 4 (or the isolation pillars arranged in the first direction) on the electroluminescent substrate falls within the orthographic projection area of the corresponding first insulating layer 3 on the electroluminescent substrate, and the corresponding first insulating layer 3 that supports the pixel isolation structure 4 can reduce the phenomenon of uneven lateral distribution of the material at the edge, thereby realizing uniform light emission; it is preferred that the lateral distance between the bottom of the isolation pillar of the pixel isolation structure 4 and the bottom of the blank layer 5 is 1 to 15 microns. Alternatively, as shown in FIG. 11, a portion of the first insulating layer 31 and the pixel isolation structure are in transverse contact, and this portion of the first insulating layer 31 also reduces the lateral uneven distribution of the material at the edges. Preferably, the transverse dimension of this portion of the first insulating layer 31 is between 1 to 15 microns (i.e., the lateral distance between the base of the isolation pillar of the pixel isolation structure 4 and the base of the blank layer 5 is between 1 to 15 micros). The “transverse direction” mentioned in this paragraph refers to the horizontal direction as shown in the schematic FIGS. 10-12.

In some embodiments, when the number of intervals is 2 or 3, the side boundary line L1 of the orthographic projection of the isolation pillars arranged in the first direction on the electroluminescent substrate coincides with the side boundary line L2 of the orthographic projection of the corresponding first insulating layer 3 on the electroluminescent substrate. Alternatively, the side boundary line of the orthographic projection of the blank layer 5 on the electroluminescent substrate is L3, with L1 being parallel to both L2 and L3, and L1 being spaced away from L2 relative to L3. In the top view of the electroluminescent substrate of FIG. 5 (the number of interval is 2), as shown in FIG. 8, L1 overlaps with L2 and L1, L2, and L3 are all parallel to each other, all represented by dashed lines.

In some embodiments, the first insulating layer 3 is uniform in thickness and material throughout the layer. There may be differences in the thickness within the layer, but the differences are also considered to be acceptable if they fall within an allowable error range.

In some embodiments, the material of the first insulating layer 3 is selected from SiNₓ, SiO₂, SiOₓN_{y} or photoresist.

In some embodiments, the materials of the first insulating layer 3 and the second insulating layer 6 are consistent, which can be synchronized when preparing the electroluminescent substrate to improve the efficiency of substrate preparation.

In some embodiments, as shown in FIG. 14, a plurality of blank layers 5 are arranged in an elongate strip shape in a pixel area, the blank layers 5 include at least one column and each blank layer 5 has the same area (with reference to the area of the top view), and the length direction of blank layers 5 aligns with (referring to the long side direction) the extension direction of the isolation pillars arranged in the first direction. The length direction of the long strip-shaped blank layer 5 matches the movement direction of the printhead of the printing device, which enhances the printing accuracy.

In some embodiments, as shown in FIG. 14, the electroluminescent substrate includes at least three pixel areas. The blank layers disposed within the first pixel area and the third pixel area are arranged both in two columns, with the area of each blank layer denoted as S1. The blank layers disposed within the second pixel area are in a single column, with area of each blank layer denoted as S2. The first pixel area, the second pixel area, and the third pixel area are arranged side by side. The area of blank layer is calculated based on the area exposed at the bottom of the corresponding groove.

In some embodiments, the pixel isolation structure further includes isolation pillars arranged in a second direction, with the width direction of the blank layer is in the same direction as the extension direction of the isolation pillars arranged in the second direction; the electroluminescent substrate includes at least three pixel areas, the blank layers disposed in the first pixel area and the third pixel area are in two columns, the area of each of the blank layers is denoted as S1, the blank layers disposed in the second pixel area are in two columns, the area of each of the blank layers is denoted as S2. The first pixel area and the third pixel area are both defined by isolation pillars arranged in the first direction and those arranged in the second direction, while the second pixel area is defined only by isolation pillars arranged in the first direction. In some preferred embodiments, the first, second, and third pixel areas are arranged as shown in FIG. 15, the first pixel area and the third pixel area are arranged adjacent to each other vertically, while the second pixel area and the first pixel area are arranged adjacent to each other horizontally, and the second pixel area and the third pixel area are arranged adjacent to each other horizontally. As shown in FIG. 15, when the blank layers are subsequently prepared with the RGB sub-pixel light-emitting elements, the three (RGB) sub-pixel light-emitting elements are arranged in the Chinese character of Pin ( [symbol] ), a pixel unit is (denoted as PX), shown in the square dashed box. The isolation pillars arranged in the second direction are introduced to prevent color mixing between adjacent pixel areas with different light-emitting colors during the preparation process.

In some embodiments, the first pixel area described above is the area for setting a red light-emitting element, the second pixel area is the area for setting a blue light-emitting element, and the third pixel area is the area for setting a green light-emitting element, and individual blank layers disposed within the same pixel area are used for setting light-emitting devices of the same light-emitting color.

In some embodiments, S1 is smaller than S2, and preferably, S2=2S1. FIG. 16 (top view of the electroluminescent substrate of FIG. 12) illustrates such embodiments, wherein PX represents a pixel unit including RGB sub-pixels.

The above “elongate strip shape” refers to any shape whose length is greater than its width, such as an oval track shape, an oval shape, a rectangle, a diamond shape, etc. Preferably, the elongate strip shape is a rectangle or an approximate rectangle, the approximate rectangle including a rectangle having at least one chamfer.

According to yet another aspect of the present disclosure, there is also provided an electroluminescent device, which may include an electroluminescent substrate as described in any of the embodiments or implementations of the present disclosure. The electroluminescent device has excellent emission uniformity.

An electroluminescent device is a light-emitting device that operates on the principle of electroluminescence, such as a quantum dot light-emitting device (QLED) and an organic light-emitting device (OLED). Such electroluminescent devices typically include a plurality of light-emitting elements, and each light-emitting element includes an anode, a cathode (also referred to as the first electrode and second electrode), and a stack of functional layers (at least including the light-emitting layer, and optionally also functional layers such as an electron injection layer, an electron transport layer, a hole transport layer, a hole injection layer, and the like) disposed between the anode and the cathode. Typically, the light-emitting layer includes individual units dedicated to each sub-pixel, while the functional layers such as the electron injection layer, the electron transport layer, the hole transport layer, the hole injection layer, etc. may be shared by a plurality of sub-pixels, and thus may also be referred to as common layers. The light-emitting layer and the functional layer of the electroluminescent device are fabricated within and above the blank layer. At least one of the light-emitting layer and the functional layer is prepared by the ink-jet printing method, thereby leveraging the advantages of the electroluminescent substrate described above.

In some embodiments, at least one column of blank layers 5 disposed between adjacent pixel isolation structure 4 is used to accommodate sub-pixel light-emitting elements of the same light-emitting color, with each blank layer 5 corresponding to a single sub-pixel light-emitting element. This approach improves printing accuracy.

In some embodiments, a red sub-pixel light-emitting element is provided in the blank layer 5 disposed within the first pixel area, a blue sub-pixel light-emitting element is provided in the blank layer 5 disposed within the second pixel area, and a green sub-pixel light-emitting element is provided in the blank layer 5 disposed within the third pixel area. The color arrangement of the sub-pixel light-emitting elements may be designed in accordance with the prior art. In some embodiments, the first, second and third pixel areas are arranged sequentially from left to right. In some embodiments, the color arrangement of the sub-pixel light-emitting elements follows the pattern R B G B R B G B R B G B. In some embodiments, the light-emitting area of the blue sub-pixel is twice the light-emitting area of the red and/or green sub-pixel because the blue light-emitting material has a shorter lifespan compared to the red and green light-emitting material.

The above-described electroluminescent devices can be used in the field of display devices.

According to a further aspect of the present disclosure, there is also provided a method of preparing an electroluminescent device, wherein an electroluminescent substrate as described in any of the embodiments or realizations of the present disclosure is used, and the electroluminescent device is prepared using an inkjet printing process. The electroluminescent device produced by the preparation method has excellent emission uniformity.

Examples of the preparation of the electroluminescent substrate and the electroluminescent device including the same according to some embodiments of the present disclosure are described below.

### Example 1

Preparation of a substrate was carried out with reference to the pixel arrangement design of FIG. 16. First, a TFT glass substrate with ITO transparent electrode is formed (as a first electrode layer) was adopted, the substrate had a plurality of polyimide (PI) layers spaced apart and having a height of 2 micrometers which were used as pixel isolation structure. The pixel isolation structure had a trapezoidal cross-section (with a side surface having an angle of inclination greater than or equal to 80° and less than 90° to the horizontal). Alternatively, the pixel isolation structure with a rectangular cross-section may be used.

The preparation process of the first insulating layer, the second insulating layer, and the interval: sputtering a layer of ITO with a thickness of 150 nm onto the TFT glass substrate, and then coating a layer of PI, and then etching a pattern of ITO by exposure and development; then sputtering a layer of SiN with a thickness of 50 nm, and then coating a layer of PI, and etching a pattern of SiN by exposure and development (i.e., the first and second insulating layers); finally, a layer of PI with a thickness of 2 μm was coated, and the pixel isolation structure was obtained by exposure and development.

A schematic cross-section of the resulting electroluminescent substrate is shown in FIG. 12.

Subsequently, optionally, the substrate can be cleaned. For example, the substrate having the pixel isolation structure was cleaned with a solvent, blown dry and subjected to plasma surface treatment to obtain a clean electroluminescent substrate.

Afterwards, a hole injection layer and a hole transport layer were fabricated. For example, an aqueous solution of PEDOT:PSS, PEDOT being a polymer of PEDOT (3,4-ethylenedioxythiophene monomer) and PSS being polystyrene sulfonate, was applied to a clean substrate in an air environment. After the coating was completed, it was annealed in air and then transferred to a glove box in a nitrogen environment for annealing. Thereby, a PEDOT:PSS layer was finally formed on the ITO surface as a hole injection layer. The n-octylbenzene solution of poly((9,9-dioctylfluorene-2,7-diyl)-co-(4,4′-(N-(4-sec-butylphenyl)diphenylamino)) (TFB) (at a concentration of 1 wt %) was then printed on the PEDOT:PSS layer by inkjet printing, and after printing was completed, it was annealed in a glove box to form the hole transport layer. In some implementations, the thickness of the hole injection layer (HIL) may ranges from tens to hundreds of nanometers, such as 20 nm to 300 nm, preferably 30 nm to 150 nm, and the thickness of the hole transport layer (HTL) may range from tens to hundreds of nanometers, such as 10 nm to 200 nm, preferably 15 nm to 100 nm.

After that, the light-emitting layer was fabricated. Quantum dot ink (quantum dots were CdZnSeS/ZnS with a concentration of 80 mg/mL, corresponding to an emission wavelength of 470 nm-485 nm) was printed on the hole transport layer. It was then transferred to a vacuum hot plate and annealed under evacuation. In some embodiments, the thickness of the QD light-emitting layer may range from tens to hundreds of nanometers, such as 10 nm to 100 nm, preferably 15 nm to 60 nm. See FIG. 17 for a microscope photograph of the device after the preparation of three (RGB) quantum dot ink layers (without drying) following excitation with UV light.

After that, the electron transport layer was fabricated. For example, a ZnO nanocrystal solution can be spin-coated on the light-emitting layer, e.g., at 2500 rpm for 50 s. After spin-coating the layer, an annealing process was performed in a glove box. A thin film of zinc oxide nanocrystals was ultimately formed on the surface of the light-emitting layer. As examples, there thicknesses may each range from tens to hundreds of nanometers, such as 10 nm to 400 nm, preferably 20 nm to 100 nm.

After that, the second electrode layer was fabricated. For example, the device obtained after the zinc oxide nanocrystalline film was prepared may be placed in a vacuum vaporization chamber to vaporize and obtain the silver electrode.

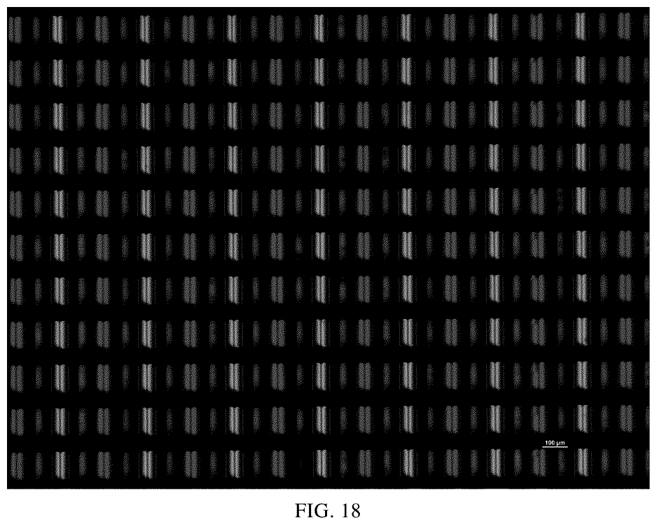

Afterwards, the substrate with the vaporized electrode can be bonded to the glass cover plate by UV adhesive, and the encapsulation can be completed after UV curing before the device was used for testing. The microscopic photograph of the obtained electroluminescent device under operating conditions is shown in FIG. 18, where the sub-pixels of the two RG colors are segmented, and it can be seen that the sub-pixels of the RGB colors have a more uniform emission at the inner edges of the sub-pixels.

### Example 2

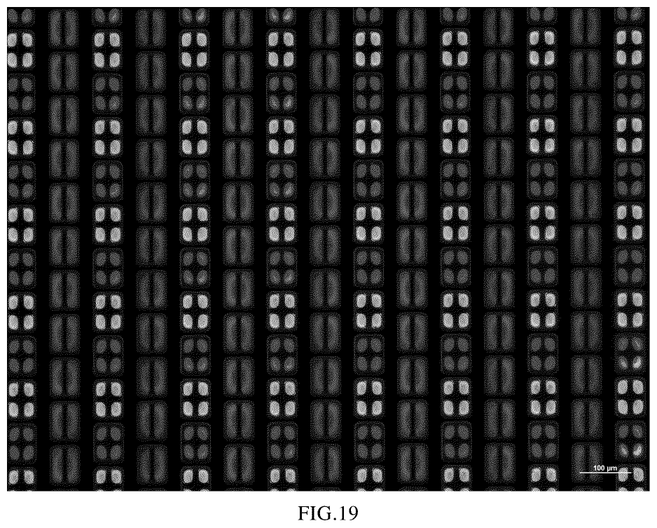

The difference from Example 1 is that the electroluminescent substrate was prepared with reference to the pixel arrangement design of FIG. 15. The obtained electroluminescent device is shown in a microscope photograph under operating conditions in FIG. 19, where the sub-pixels of the RGB are all segmented, and it can be seen that the inner edges of the sub-pixels of the RGB emit light more uniformly.

It should be noted that the inkjet printing ink formulation and the inkjet printing process also have an impact on the emission uniformity effect, i.e. the emission uniformity can continue to be improved around these two aspects.

In the specification and claims, terms such as “left”, “right”, “front”, “back”, “top”, ‘bottom’, “high”, “low”, etc., are used for descriptive purposes and not necessarily to indicate fixed relative positions. It should be understood that these words so used are interchangeable where appropriate, enabling the embodiments of the present disclosure described herein, for example, to operate in other orientations than those shown or otherwise described herein. For example, when the device in the accompanying drawings is inverted, features originally described as being “above” other features may be described as being “below” other features. The device may also be oriented in other ways (rotated 90 degrees or in other orientations), and the relative spatial relationships will be interpreted accordingly.

In the specification and the claims, when an element is described as being “on top of”, “attached to”, “connected to”, or “coupled to” another element, etc., the element may be directly above the other element, directly attached to the other element, directly connected to the other element, directly coupled to the other element, there may be one or more intermediate elements. By contrast, an element is said to be “directly” above another element, “directly attached” to another element, “directly connected” to another element, or “directly coupled” to another element, there are no intermediate elements present. In the specification and claims, when a feature is arranged to be “adjacent” to another feature, it can mean that a feature has a portion that overlaps an adjacent feature or is disposed above or below an adjacent feature.

As used herein, the term “exemplary” means “used as an example, instance, or illustration” and not as a “model” to be precisely reproduced. The implementations described herein exemplarily are not necessarily to be construed as preferred or advantageous over other implementations. Furthermore, the present disclosure is not limited by any expressed or implied theories given in the art, the background art, the content of the invention, or the specific embodiments.

As used herein, the term “substantially” is intended to encompass any small variation due to design or manufacturing defects, tolerances of the device or component, environmental influences, and/or other factors. The term “substantially” also allows for variations from the perfect or ideal situation due to parasitic effects, noise, and other practical considerations that may be present in the actual implementation.

In addition, the terms “first,” “second,” and the like may be used herein for reference purposes only and are thus not intended to be limiting. For example, the words “first,” “second,” and other such numerical terms relating to structures or components do not imply order or sequence unless the context clearly indicates otherwise.

It should also be understood that the term “including/containing” as used herein indicates the presence of the indicated features, integrals, steps, operations, units, and/or components, but does not preclude the presence or addition of one or more other features, integrals, steps, operations, units, and/or components, and/or combinations thereof.

For the purposes of this disclosure, the term “providing” is used broadly to encompass all ways of obtaining an object, so that “providing an object” includes, but is not limited to, “purchasing”, “preparing/manufacturing,” ‘arranging/setting up,’ ‘installing/assembling,’ and/or ‘ordering’ an object, etc.

As used herein, the term “and/or” includes any and all combinations of one or more of the listed items in association. The terms used herein are for the purpose of describing particular embodiments only and are not intended to limit the present disclosure. As used herein, the singular forms “one,” “a,” and “the” are also intended to include the plural form unless the context clearly indicates otherwise.

As used herein, “substantially” or “approximately” is intended to include, in addition to full compliance with certain conditions, errors in the measurement related to the measurement of specific quantities (i.e., limitations of the measurement system) and acceptable deviations based on the desired technical effect, as contemplated by a person of ordinary skill in the art. Technical effect is determined to be within the range of acceptable deviations.

One of skill in the art should realize that the boundaries between the operations described above are merely illustrative. Multiple operations may be combined into a single operation, the single operation may be distributed among additional operations, and the operations may be performed at least partially overlapping in time. Moreover, alternative embodiments may include multiple instances of a particular operation, and the order of operations may be altered in various other embodiments. However, other modifications, variations and substitutions are equally possible. Aspects and elements of all embodiments disclosed above may be combined in any manner and/or in combination with aspects or elements of other embodiments to provide multiple additional embodiments. Accordingly, this specification and the accompanying drawings should be viewed as illustrative and not limiting.

While some particular embodiments of the present disclosure have been described in detail by way of examples, it should be understood by those skilled in the art that the above examples are for illustrative purposes only and are not intended to limit the scope of the present disclosure. The embodiments disclosed herein may be combined in any combination without departing from the spirit and scope of the present disclosure. It should also be understood by those skilled in the art that multiple modifications can be made to the embodiments without departing from the scope and spirit of the present disclosure. The scope of the present disclosure is limited by the appended claims.

What is claimed is:

1. An electroluminescent substrate, characterized in that the electroluminescent substrate comprises a substrate layer comprising pixel driving circuitry, and an array of pixel areas disposed on the substrate layer; the pixel areas being defined by a pixel isolation structure, at least a portion of the pixel areas comprising a first electrode layer, a first insulating layer disposed on the first electrode layer, and a plurality of blank layers; each blank layer being formed by and surrounded by at least a portion of the first insulating layer and separated from each other, the pixel isolation structure having a thickness greater than the thickness of the first insulating layer;
the pixel isolation structure comprising a plurality of isolation pillars arranged in at least one direction; an orthographic projection of the pixel isolation structure on the electroluminescent substrate does not overlap with an orthographic projection of the blank layer on the electroluminescent substrate;
the interior of the first electrode layer corresponding to at least a portion of the pixel areas has an interval such that the first electrode layer is disconnected and forms a plurality of sub-first electrode layers arranged in a mutually spaced manner, the interior of the first insulating layer also being separated by the interval; the number of the intervals in the at least a portion of the pixel areas is greater than or equal to 1; a second insulating layer is provided inside the intervals;
the electroluminescent substrate further comprising one or both of feature A and feature B,
the feature A being that the pixel isolation structure is disposed on a portion of the first insulating layer, the orthographic projection of the pixel isolation structure on the electroluminescent substrate falls within an area of the orthographic projection of the corresponding first insulating layer on the electroluminescent substrate;
the feature B characterized in that the pixel isolation structure is disposed on a portion of the first electrode layer and at least a portion of the first insulating layer and the pixel isolation structure are disposed in transverse contact.

2. The electroluminescent substrate according to claim 1, characterized in that the first insulating layer has a thickness of less than 700 nm.

3. The electroluminescent substrate according to claim 1, characterized in that the pixel isolation structure has a thickness of 0.7 to 2 μm.

4. The electroluminescent substrate according to claim 1, characterized in that the depth of the interval does not reach the substrate layer, and the thickness of the second insulating layer is less than or equal to the thickness of the first electrode layer.

5. The electroluminescent substrate according to claim 1, characterized in that the second insulating layer is in contact with the substrate layer or the second insulating layer is disposed within the substrate layer, preferably, the second insulating layer has a thickness of less than 700 nm.

6. The electroluminescent substrate according to claim 1, characterized in that a side boundary line L1 of the orthographic projection of the isolation pillar arranged along a first direction on the electroluminescent substrate is parallel to a side boundary line L3 of the orthographic projection of the blank layer on the electroluminescent substrate, with the shortest distance d1 between L1 and L3 being 1 to 15 μm.

7. The electroluminescent substrate according to claim 1, characterized in that the width d2 of the interval ranges from 1 to 15 μm.

8. The electroluminescent substrate according to claim 1, characterized in that within a single pixel area: the number of the intervals is 1, the interval is disposed in the center of the pixel area, and the blank layer corresponding to the pixel area has two columns; or, the number of the intervals is 2, each of the intervals is adjacent to one side of the isolation pillar arranged in a first direction, and the pixel area corresponding to the blank layer has one column; or, the number of the intervals is 3, two of the intervals are each adjacent to one side of the isolation pillar arranged in a first direction, one interval is disposed in the center of the pixel area, and the blank layer corresponding to the pixel area has two columns.

9. The electroluminescent substrate according to claim 8, characterized in that when the number of the intervals is 2 or 3, a side boundary line L1 of the orthographic projection of the isolation pillars arranged in the first direction on the electroluminescent substrate overlaps with a side boundary line L2 of the orthographic projection of the corresponding the first insulating layer on the electroluminescent substrate, or the orthographic projection of the blank layer on the electroluminescent substrate has a side boundary line L3, L1 is parallel to L2 and L3, and L1 is spaced away from the L3.

10. The electroluminescent substrate according to claim 1, characterized in that the first insulating layer is uniform in thickness and material throughout the layer.

11. The electroluminescent substrate according to claim 1, characterized in that the material of the first insulating layer is selected from SiNₓ or SiO₂.

12. The electroluminescent substrate according to claim 1, characterized in that the plurality of blank layers are arranged in an elongate strip shape within a single pixel area, the blank layer comprising at least one column and each blank layer has the same area, and the length direction of the blank layers being the same as the extension direction of the isolation pillars arranged in a first direction.

13. The electroluminescent substrate according to claim 12, characterized in that the electroluminescent substrate comprises at least three pixel areas, the blank layers disposed in the first and the third pixel areas are both in two columns and each blank layer has an area of S1, the blank layer disposed in the second pixel area is in one column and each blank layer has an area of S2, the first, second and third pixel areas are arranged side by side.

14. The electroluminescent substrate according to claim 12, characterized in that the pixel isolation structure further comprises isolation pillars arranged in a second direction, the width direction of the blank layer being in the same direction as the extension direction of the isolation pillars arranged in the second direction; the electroluminescent substrate comprising at least three pixel areas, the blank layers disposed in the first and third pixel areas being in two columns and area of each of the blank layers is S1, the blank layers disposed within the second pixel area are in two columns and area of each of the blank layers is S2, the first and third pixel areas are both defined by the isolation pillars arranged in the first direction and the isolation pillars arranged in the second direction, and the second pixel area is defined only by the isolation pillars arranged in the first direction.

15. The electroluminescent substrate according to any one of claims 13 or 14, characterized in that the first pixel area is the area for setting a red light-emitting element, the second pixel area is the area for setting a blue light-emitting element, the third pixel area is the area for setting a green light-emitting element, and each of the blank layers disposed in the same pixel area is used for setting light-emitting elements of the same light-emitting color.

16. The electroluminescent substrate according to claim 15, characterized in that S1 is smaller than S2, preferably, S2=2S1.

17. An electroluminescent device, characterized in that it comprises an electroluminescent substrate as claimed in any one of claims 1 to 16.
